(19) United States
(12) Patent Application Publication
(10) Pub. No.: US 2007/0126050 A1
(43) Pub. Date: Jun. 7, 2007

(54) Flash memory cell and fabrication method thereof

(75) Inventor: Sung Jin Kim, Busan (KR)

Correspondence Address: PILLSBURY WINTHROP SHAW PITTMAN, LLP, P.O. BOX 10500, MCLEAN, VA, 22102, US

(73) Assignee: DONGBUANAM SEMICONDUCTOR INC., Seoul (KR)

(21) Appl. No.: 11/319,410

(22) Filed: Dec. 29, 2005

(30) Foreign Application Priority Data
Sep. 20, 2005 (KR) 10-2005-0087281

(51) Int. Cl. H01L 29/788

(52) U.S. Cl. 257/315

(57) ABSTRACT

A flash memory cell transistor is presented that includes a stacked structure of successively formed tunnel oxide layer, floating gate, inter-gate insulating layer and control gate on a semiconductor substrate, an insulating thin film formed on a first sidewall of the stacked structure, and an access gate formed on the first sidewall of the stacked structure while interposing the insulating thin film. A drain region is formed in a first region of the substrate in which the first region is exposed by the floating gate and a source region is formed in a second region of the substrate in which the second region is exposed by the access gate. The access gate overlaps, along the vertical direction of the stacked structure, the control gate and the floating gate.

### BACKGROUND OF THE INVENTION

1. Related Application and Priority Information

This application claims the benefit of Korean Application No. 10-2005-0087281, filed on Sep. 20, 2005, which is hereby incorporated by reference in its entirety.

2. Field of the Invention

The present invention relates to flash memory technologies. More specifically, the present invention relates to a cell transistor of flash memory device that can reduce the cell size and fabrication method thereof.

3. Description of the Related Art

Electrically erasable programmable read only memory (EEPROM) type flash memory is one of the most prominent nonvolatile memories, and takes advantages of small cell size of electrically programmable read only memory (EPROM) and electrical erase feature of EEPROM. The flash memory, which is capable of retaining the stored data without continued supply of electrical power, is generally divided into two types based on their cell structure: Intel ETOX cell (or simply ETOX cell) having stacked structure and split gate cell consisting of two transistors per cell.

FIG. 1 is a cross-sectional view showing the structure of conventional ETOX cell transistor of a flash memory device. The conventional ETOX cell transistor comprises a tunnel oxide 12 formed on an active region in a semiconductor substrate 10, and successively stacked layers of floating gate 14, inter-gate insulating layer 16 and control gate 18 on the tunnel oxide 12. Source/drain region 20 is formed in the substrate 10 and defines a channel region under the floating gate 14.

The ETOX cell is programmed by applying a programming voltage to both the control gate 18 connected to a word line and the drain connected to a bit line. The source is grounded. The positive charge on the control gate 18 results in avalanche or hot electron injection near the drain 20 and into the floating gate 14 through the tunnel oxide 12.

The ETOX cell is erased by applying an erase voltage to the source 20 connected to a source line. The drain is left open (floating) and the control gate is grounded. Electrons trapped in the floating gate 14 are drawn off the floating gate through the thin tunnel oxide 12 to the channel region, which results in the reduction of the cell transistor.

The conventional ETOX cell transistor occupies small area because of its three-dimensional stacked structure but has problems with over-erase when the cell is in an erase operation. Further the conventional ETOX structure has a drawback in that the effective cell size is increased because it is required to form drain contacts along the bit line.

FIG. 2 is a cross-sectional view of conventional split gate cell transistor of a flash memory device. The split gate cell comprises a tunnel oxide 32 formed on a semiconductor substrate 30, a floating gate 34 formed on the tunnel oxide 32, inter-gate insulating layer 36 formed on the substrate to mount on the floating gate 34, a control gate 38 formed on the inter-gate insulating layer 36 to overlap part of the floating gate 34, and source/drain 40 formed in the substrate under the control gate 38 and the floating gate 34. The programming and erase operations of the split gate flash memory is similar to the operations of the ETOX structure.

The split gate flash memory has a combined structure of a selective transistor which does not have the floating gate and a cell transistor which has the partly overlapped floating gate and control gate. Therefore, unit cell size is increased due to the additional selective transistor. However, the split gate flash memory can avoid the over-erase problem because of the selective transistor. Nonetheless, the conventional split gate flash memory has an increased critical dimension (CD) and degraded electrical characteristics, because the control gate has an overlapped region with the floating gate.

### SUMMARY OF THE INVENTION

Principles of the present invention, as embodied and broadly described herein, are directed to providing a new structure of the flash memory device that has smaller cell size than the split gate cell and prevents the over-erase problem and a manufacturing method for fabricating the same. That is, the present invention provides a flash memory cell transistor which includes a stacked structure of floating gate and control gate and an access gate overlap in vertical direction of the stacked structure the floating gate and the control gate. The cell transistor has reduced cell size and can avoid the over-erase problem.

In an embodiment of the present invention, the cell transistor comprises a stacked structure of successively formed tunnel oxide layer, floating gate, inter-gate insulating layer and control gate on a semiconductor substrate, an insulating thin film formed on a first sidewall of the stacked structure, an access gate formed on the first sidewall of the stacked structure while interposing the insulating thin film, a drain region formed in a first region of the substrate, the first region being exposed by the floating gate, and a source region formed in a second region of the substrate, the second region being exposed by the access gate.

In another embodiment of the present invention, a method for forming a flash memory cell transistor is presented. The method comprises forming a stacked structure of successively formed tunnel oxide layer, floating gate, inter-gate insulating layer and control gate on a semiconductor substrate, forming a drain region in a first region of the substrate and a source region in a second region of the substrate, the first region being exposed by the floating gate and the second region being distant from the first region, forming an insulating thin film on a first sidewall of the stacked structure, and forming an access gate on the first sidewall of the stacked structure while interposing the insulating thin film.

### BRIEF DESCRIPTION OF DRAWINGS

The accompanying drawings, which are incorporated in and constitute a part of this Specification, depict corresponding embodiments of the invention, by way of example only, and it should be appreciated that corresponding reference symbols indicate corresponding parts. In the drawings:

FIG. 1 is a cross-sectional view of the ETOX cell transistor of the conventional flash memory device;

FIG. 2 is a cross-sectional view of the split gate cell transistor of the conventional flash memory device;

FIG. 3 is a cross-sectional view of a flash memory cell transistor according to the present invention; and

FIGS. 4A to 4G illustrate, in cross-sectional views, the processes for fabricating the flash memory cell transistor according to the present invention.

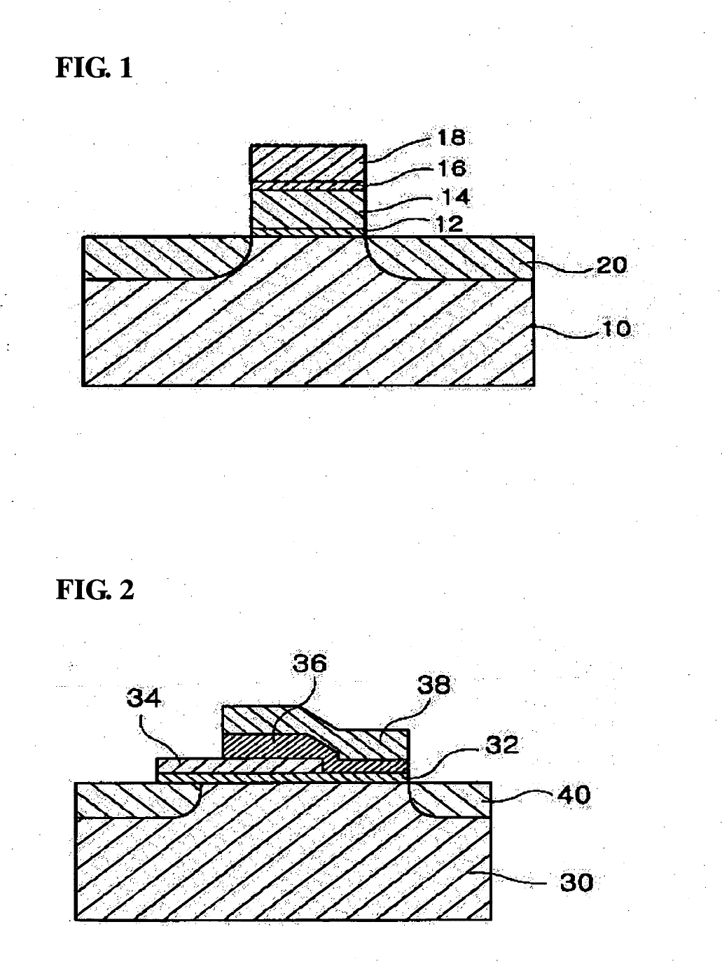

### DETAILED DESCRIPTION OF THE INVENTION

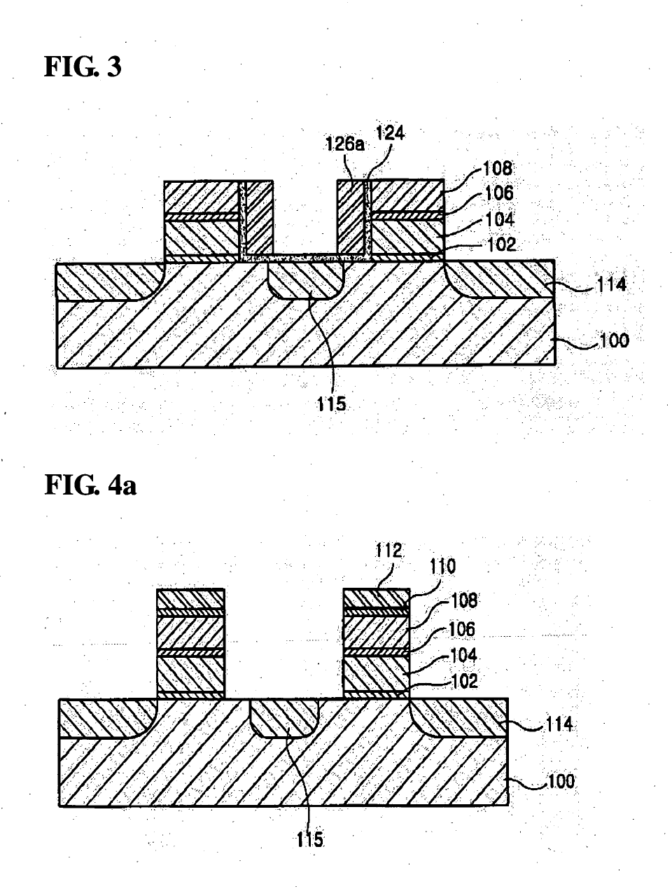

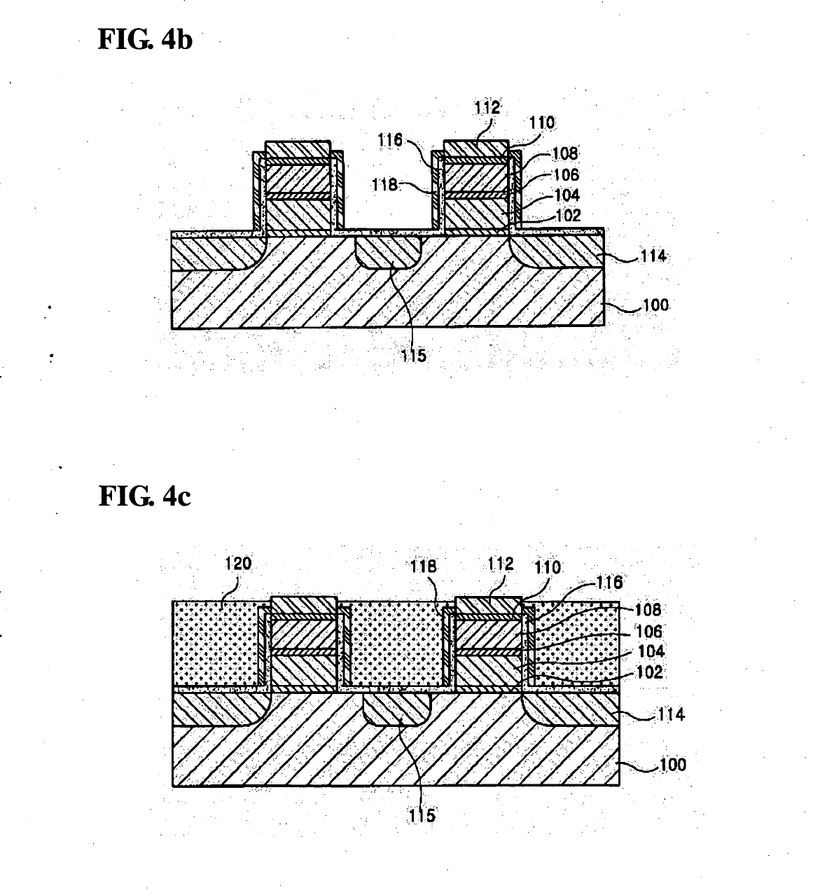

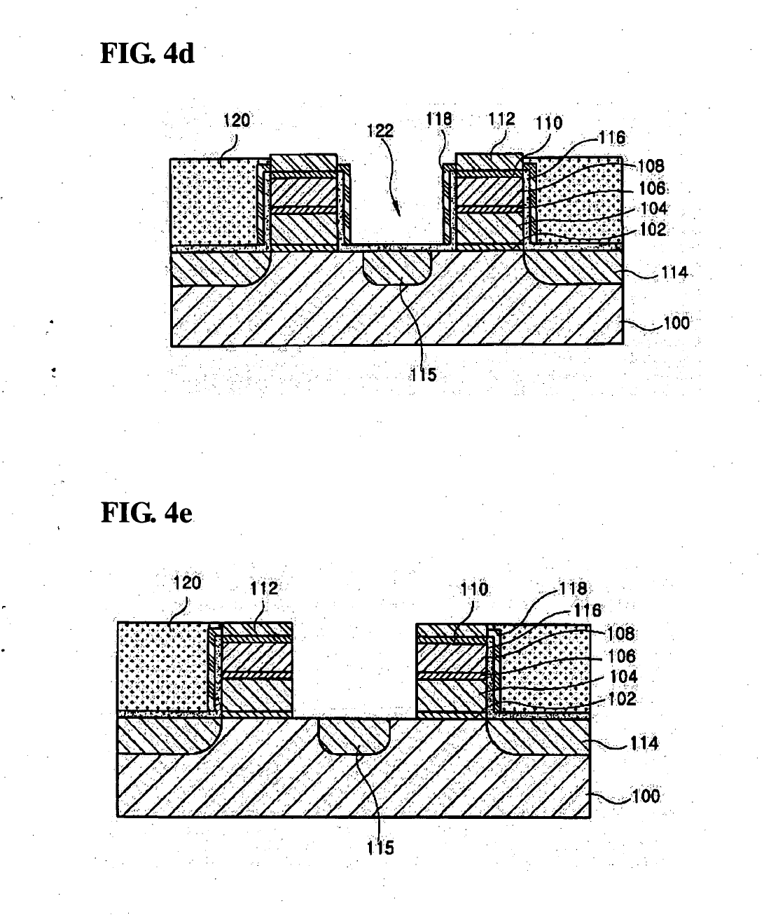

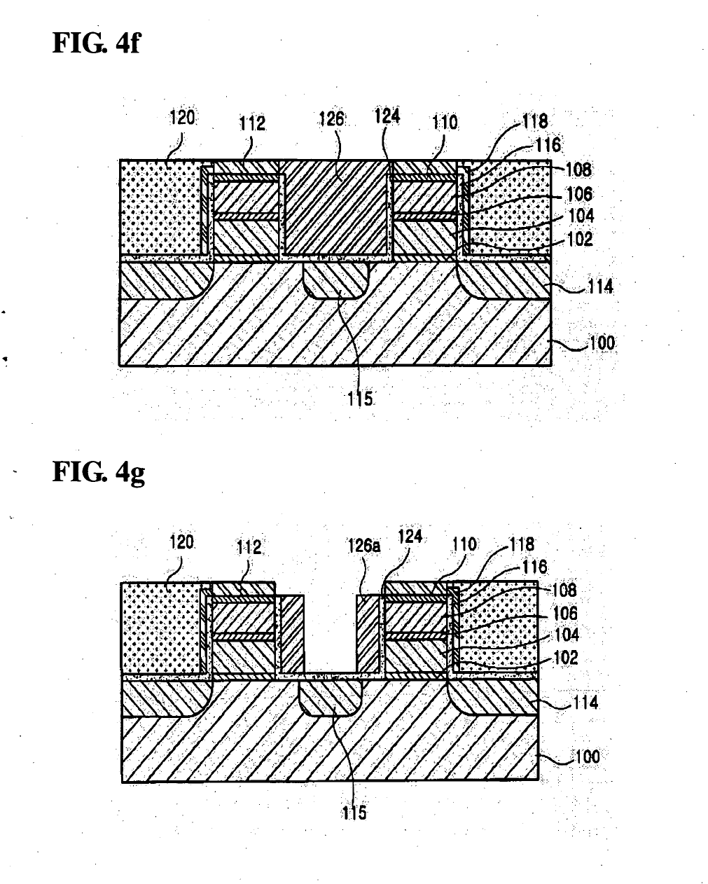

Hereinafter, embodiments of a nonvolatile memory device and fabrication method thereof, according to the present invention, will be described with reference to FIGS. 3 and 4A to 4G

FIG. 3 shows, in cross-sectional view, the structure of a flash memory cell transistor according to the present invention. The memory cell transistor comprises a tunnel oxide 102 formed on an active region in a semiconductor substrate 100, and successively stacked floating gate 104, inter-gate insulating layer 106 and control gate 108 on the tunnel oxide 102.

In an embodiment of the present invention, the floating gate 104 and the control gate 108 are made of conductive material such as doped polysilicon, tungsten (W), and tungsten silicide (WSi). The floating gate 104 and the control gate 108 may be either a single conductive metal or multiple layers of the conductive materials above mentioned. The inter-gate insulating layer 106 is made of at least one of silicon dioxide (SiO₂), silicon nitride (Si₃N₄) and high permittivity dielectric. Oxide-nitride-oxide (ONO) or Ta₂O₅ can be used for the inter-gate insulating layer 106.

The cell transistor of the present invention includes an insulating thin film 124 which is made of, for example, silicon dioxide (SiO₂) and formed on the sidewalls from the tunnel oxide 102 to the control gate 108. Further, the cell transistor comprises an access gate 126a on the sidewalls from the tunnel oxide 102 to the control gate 108 while interposing the insulating thin film 124. The access gate 126a is made of single conductive material or multiple layers of conductive material such as doped polysilicon, metal and metal silicide. The insulating thin film 124 covers the substrate region where the access gate 126 lies.

Drain region 114 of the cell transistor is formed in the substrate region exposed by the floating gate 104, and source region 115 is formed the substrate region exposed by the access gate 126a. The drain and source are highly diffused regions by N-type dopants (such as P and As) or P-type dopants (such as B).

In an embodiment of the present invention, the source region 115 is commonly shared by neighboring two cell transistors. Further, the drain region 114 below the floating gate 104 and the source region 115 under the access gate 126a define a channel region through which the dopant carriers flow.

Though not shown in the figures, the cell transistor further comprises at least two dielectric layers having an etch selectivity on the control gate 108. For instance, a thin silicon dioxide (SiO₂) is deposited on the control gate 108, and a relatively thicker silicon nitride (Si₃N₄) is deposited on the silicon oxide.

FIGS. 4A to 4G are cross-sectional views for illustrating the fabrication steps for the flash memory cell transistor according to the present invention. First, referring to FIG. 4A, silicon dioxide is deposited by e.g., chemical vapor deposition (CVD) on a semiconductor substrate 100 made of, for example. silicon, and the silicon dioxide is selectively etched to form the tunnel oxide layer 102.

Next, doped polysilicon, ONO, and doped polysilicon are successively deposited on the tunnel oxide layer 102 and patterned by a photolithographic technique using a gate mask to form a stack structure of the doped polysilicon, ONO, doped polysilicon and tunnel oxide layer. Therefore, stacked structure of the tunnel oxide 102, floating gate 104 of the doped polysilicon, the inter-gate insulating layer 106 of the ONO, and the control gate 108 of the doped polysilicon is obtained.

In an embodiment of the present invention, at least two dielectric layers 110 and 112 are stacked on the control gate 108. The dielectric layers 110 and 112 may be formed by depositing thin silicon dioxide on the substrate to cover the top surface of the control gate 108, depositing relatively thicker silicon nitride on the deposited silicon dioxide, and selectively etching the thin silicon dioxide and the thick silicon nitride by a photolithographic process.

By performing ion implantation process into the substrate through the stacked structure, the drain region 114 is formed in the substrate. The source region 115 is formed by injecting dopant ions or atoms into the substrate through the access gate 126a. The drain and source regions 114 and 115 are highly diffused regions of N-type dopants (such as P and As) or P-type dopants (such as B).

Referring to FIG. 4B, the insulating thin film 116 made of e.g., SiO₂ is formed by re-oxidation is formed on the sidewalls of the stacked structure and on the exposed substrate surface. Subsequently, silicon nitride is deposited by CVD on the insulating thin film 116, and is etched-back to form sidewall spacers 118 on sidewalls of the stacked structure.

Referring to FIG. 4C, insulating material such as O₃-TEOS is deposited by, for example, CVD on the substrate to form the interlayer dielectric layer 120 which covers the substrate surface and fills the space between a plurality of the stacked structures. The interlayer dielectric layer 120 is polished by, for example, chemical mechanical polishing (CMP) process until the silicon nitride 112 on the control gate 108 is exposed.

Next, a photoresist pattern (not shown) to open the source region is formed, and portions of the interlayer dielectric layer 120 that lies on the source region are removed by e.g., wet etching process using HF solution. Then, the photoresist pattern is removed by, for example, O₃ plasma etching process. With these processing steps, the insulating thin film 116 of SiO₂ and silicon nitride spacers 118 are exposed in source area 122 as shown in FIG. 4D.

Referring to FIG. 4E, the exposed insulating thin film 116 and silicon nitride spacers 118 are removed by wet or dry etching method to expose the substrate region on the source region 115. At this stage, part of the silicon nitride 112 on the control gate 108 is etched.

Referring to FIG. 4F, an insulating thin film 124 is formed on the sidewalls of the stacked structure and on the substrate surface in the source region 115. The insulating thin film 124 is made of SiO₂ by wet or dry oxidation.

Doped polysilicon 126 as the conductive material fills the gap between the control gates 108 where the insulating thin film 124 is formed. The conductive material 126 is formed by CVD and covers the top surface of the control gate 108 or the silicon nitride 112 on the control gate 108.

Subsequently, as shown in FIG. 4G, the conductive material 126 is selectively etched by a photolithographic process using an access gate mask to form the access gate 126a on the insulating thin film 124 at the sidewalls of the stacked structure. It should be noted that the access gate 126a is formed only the sidewalls of the stacked structure, which are adjacent to the source region 115. Therefore, the access gate 126a overlaps in vertical direction the control gate 108 and the floating gate 104.

Since the flash memory cell transistor has the vertically overlapping access gate with the control gate and the floating gate, the cell size can be reduced than the conventional split gate cell transistor and prevent operational failure due to the over-erase.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A flash memory cell transistor comprising:
a stacked structure of successively formed tunnel oxide layer, floating gate, inter-gate insulating layer and control gate on a semiconductor substrate;
an insulating thin film formed on a first sidewall of the stacked structure;
an access gate formed on the first sidewall of the stacked structure while interposing the insulating thin film;
a drain region formed in a first region of the substrate, the first region being exposed by the floating gate; and
a source region formed in a second region of the substrate, the second region being exposed by the access gate.

2. The flash memory cell transistor of claim 1 further comprising at least two dielectric layers formed on the control gate.

3. The flash memory cell transistor of claim 2, wherein the two dielectric layers are made of insulating material having etching selectivity.

4. The flash memory cell transistor of claim 1, wherein the floating gate comprises single or multiple layers of doped silicon, metal, and metal silicide.

5. The flash memory cell transistor of claim 1, wherein the control gate comprises single or multiple layers of doped silicon, metal, and metal silicide.

6. The flash memory cell transistor of claim 1, wherein the access gate comprises single or multiple layers of doped silicon, metal, and metal silicide.

7. The flash memory cell transistor of claim 1, wherein the insulating thin film extends to the second region of the substrate and to a neighboring flash memory cell transistor.

8. A method for forming a flash memory cell transistor, the method comprising:
forming a stacked structure of successively formed tunnel oxide layer, floating gate, inter-gate insulating layer, and control gate on a semiconductor substrate;
forming a drain region in a first region of the substrate and a source region in a second region of the substrate, the first region being exposed by the floating gate and the second region being distant from the first region;
forming an insulating thin film on a first sidewall of the stacked structure; and
forming an access gate on the first sidewall of the stacked structure while interposing the insulating thin film.

9. The method of claim 8, wherein the formation of the stacked structure includes at least two dielectric layers on the control gate.

10. The method of claim 9, wherein the two dielectric layers comprise insulating material having etching selectivity.

11. The method of claim 8, wherein the floating gate comprises a single or multiple layers of doped silicon, metal, and metal silicide.

12. The method of claim 8, wherein the control gate comprises a single or multiple layers of doped silicon, metal, and metal silicide.

13. The method of claim 8, wherein the access gate comprises a single or multiple layers of doped silicon, metal, and metal silicide.

14. The method of claim 8, wherein the insulating thin film extends to the second region of the substrate and to a neighboring flash memory cell transistor.

15. The method of claim 8, wherein the substrate is made of silicon and the insulating thin film comprises silicon dioxide by a re-oxidation method.
